(19) United States
(12) Patent Application Publication
(10) Pub. No.: US 2025/0204154 A1
(43) Pub. Date: Jun. 19, 2025

(54) ARRAY BASE PLATE, DISPLAY PANEL, AND METHOD FOR MANUFACTURING DISPLAY PANEL

(71) Applicants: Hefei Visionox Technology Co., Ltd., Hefei (CN); KunShan Go-Visionox Opto-Electronics Co., Ltd., Kunshan (CN)

(72) Inventors: Jie WANG, Hefei (CN); Zhancheng MIAO, Hefei (CN); Dandan SUN, Hefei (CN); Zhe DU, Hefei (CN); Qing BAI, Hefei (CN); Yafei SUN, Hefei (CN); Jianjun LU, Hefei (CN); Feng ZHANG, Hefei (CN); Junfeng LI, Hefei (CN)

(73) Assignees: Hefei Visionox Technology Co., Ltd., Hefei (CN); KunShan Go-Visionox Opto-Electronics Co., Ltd., Kunshan (CN)

(21) Appl. No.: 19/066,194

(22) Filed: Feb. 28, 2025

Related U.S. Application Data
(63) Continuation of application No. PCT/CN2023/072044, filed on Jan. 13, 2023.

(30) Foreign Application Priority Data
Sep. 29, 2022 (CN) 202211199942.8

(51) Int. Cl. H10K 59/121; H10D 86/40; H10K 59/12; H10K 59/124; H10K 59/131

(52) U.S. Cl. CPC H10K 59/1213; H10D 86/481; H10K 59/1201; H10K 59/124; H10K 59/131

(57) ABSTRACT

The present application relates to an array base plate, a display panel, and a method for manufacturing an array base plate, and the array base plate includes: a substrate; a device layer stacked on a side of the substrate along a thickness direction thereof, wherein the device layer includes a first type transistor, a second type transistor, and a capacitor, the first type transistor includes a first source-drain electrode, the second type transistor includes a second source-drain electrode, and the capacitor includes a first electrode plate and a second electrode plate; wherein the first electrode plate is provided on the same layer as at least one of the first source-drain electrode and the second source-drain electrode, and the second electrode plate is provided on a side of the first type transistor and the second type transistor away from the substrate along the thickness direction.

### CROSS-REFERENCE TO RELATED APPLICATION

The present application is a continuation application of International Application No. PCT/CN2023/072044, filed on Jan. 13, 2023, which claims priority to Chinese Patent Application No. 202211199942.8 filed on, Sep. 29, 2022, and titled “ARRAY BASE PLATE, DISPLAY PANEL, AND METHOD FOR MANUFACTURING DISPLAY PANEL”, all of which are hereby incorporated by reference in their entireties.

### TECHNICAL FIELD

The present application relates to the field of display technology, and particularly to an array base plate, a display panel, and a method for manufacturing an array base plate.

### BACKGROUND

With the continuous improvement and technological change of high-resolution and high-refresh technology in the field of display, users put higher and higher demands on battery life of mobile terminal products. Low temperature polycrystalline oxide (LTPO) technology integrates advantages of low leakage of indium gallium zinc oxide (IGZO) and high mobility of low temperature poly-silicon (LTPS), and application of low frequency display in small and medium-sized panels is achieved, and the battery life of the products is greatly increased.

Since the array base plate in the LTPO technology is an extension of the LTPS array, a capacitor structure is located between an LTPS device and an IGZO device, and it is difficult to increase an area of an electrode plate of a storage capacitor, which is not helpful for increasing the resolution.

### SUMMARY

Embodiments of the present application provide an array base plate, a display panel, and a method for manufacturing an array base plate, and by the array base plate changing a location of a capacitor, an electrode plate of the capacitor may be extended or offset to increase a capacitance area, which is helpful for increasing the resolution. Meanwhile, a risk of a signal crosstalk can be reduced where the capacitor is provided.

In one embodiment, an array base plate is provided according to the embodiments of the present application, and includes: a substrate; a device layer stacked on a side of the substrate along a thickness direction thereof, wherein the device layer includes a first type transistor, a second type transistor, and a capacitor, the first type transistor includes a first source-drain electrode, the second type transistor includes a second source-drain electrode, and the capacitor includes a first electrode plate and a second electrode plate; wherein the first electrode plate is provided on the same layer as at least one of the first source-drain electrode and the second source-drain electrode, and the second electrode plate is provided on a side of the first type transistor and the second type transistor away from the substrate along the thickness direction.

Some embodiments of the present application provide a display panel including the above array base plate.

Some embodiments of the present application provide a method for manufacturing an array base plate, including:
providing a base plate, wherein the base plate includes a substrate, a first active region and a second active region located on the substrate, a first gate opposite to and insulated from the first active region, a second gate opposite to and insulated from the second active region, and a first insulation layer group covering a side of the first active region and the second active region away from the substrate along a thickness direction of the base plate;
patterning the first insulation layer group, and forming a first via and a second via on the first insulation layer group, wherein the first active region is partially exposed by the first via, and the second active region is partially exposed by the second via;
forming a first source-drain electrode connected to the first active region, a second source-drain electrode connected to the second active region, and a first electrode plate on a side of the first insulation layer group away from the substrate;
forming a second insulation layer on a side of the first source-drain electrode, the second source-drain electrode, and the first electrode plate away from the substrate; and
forming a second electrode plate on a side of the second insulation layer away from the substrate, wherein the second electrode plate and the first electrode plate jointly form a capacitor.

In the array base plate, the display panel, and the method for manufacturing the array base plate according to the embodiments of the present application, the array base plate includes the substrate and the device layer, the device layer is provided on the side of the substrate along the thickness direction thereof and includes the first type transistor, the second type transistor, and the capacitor, the first type transistor includes the first source-drain electrode, the second type transistor includes the second source-drain electrode, and the first electrode plate of the capacitor is provided on the same layer as at least one of the first source-drain electrode and the second source-drain electrode, the second electrode plate of the capacitor is provided on a side of the first type transistor and the second type transistor away from the substrate along the thickness direction, that is, the second electrode plate is provided above the first type transistor and the second type transistor, and the second electrode plate of the capacitor may be extended or offset outwards to increase the capacitance area, to satisfy a requirement of a high resolution.

### BRIEF DESCRIPTION OF THE DRAWINGS

Embodiments of the present application will be described below with reference to the accompanying drawings.

FIG. 1 is a schematic structural view of an array base plate according to an embodiment of the present application;

FIG. 2 is a schematic structural view of a display panel according to an embodiment of the present application;

FIG. 3 is a schematic flow chart of a method for manufacturing an array base plate according to an embodiment of the present application;

FIG. 4 to FIG. 18 are schematic structural views corresponding to respective steps in a method for manufacturing an array base plate according to an embodiment of the present application.

### DETAILED DESCRIPTION

Embodiments of the present application will be described in detail below. Numerous specific details are set forth in the following detailed description to provide a thorough understanding of the present application. However, embodiments of the present application may be practiced without some of these specific details. The following description of the embodiments is merely intended to provide a better understanding of the present application by illustrating examples of the present application. In the accompanying drawings and the following description, at least some of well-known structures and techniques are not shown to avoid unnecessary obscurity of the present application. In addition, size of some structures may be exaggerated for clarity. Furthermore, the features, structures, or characteristics described below may be combined in one or more embodiments by any suitable manner.

The directional words appearing in the following description indicate directions shown in the drawings and do not limit the specific structure of the array base plate, a display panel, and a method for manufacturing an array base plate according to the present application. In the description of the present application, it should be further noted that, unless otherwise clearly specified and limited, the terms “installation” and “connection” should be understood in a broad sense, for example, the “connection” may refer to a fixed, a detachable or an integrated connection; and it may refer to a director an indirect connection. The specific meaning of the terms mentioned above in the present application may be understood in accordance with specific situations.

An array structure in the LTPO technology is an extension of the LTPS array, a main capacitor structure is located between an LTPS device and an IGZO device, both a grain boundary repair and a capacitor function of the LTPS should be taken into account at the same time, and there are many signals in the same or adjacent layers of the capacitor. The dielectric layer tends to be thin, and the dielectric tends to be large, and gate potential of a driving transistor is easily affected by other signal crosstalk, resulting in a decrease in display quality. Because that a back shield metal (BSM) and gates of the driving transistors are shared in IGZO, it is difficult to increase a storage capacitance by increasing a plate area. It is necessary to introduce layers of metals to form capacitors when facing with the very high PPI product, and the capacitors are connected in parallel to increase a total capacitance, but a risk of the signal crosstalk is increased along a vertical direction and a side direction, which is difficult to balance.

In order to solve the above problem, embodiments of the present application provide an array base plate, and by the array base plate changing a location of a capacitor, an electrode plate of the capacitor may be extended or offset to increase a capacitance area, which is helpful for increasing the resolution. Meanwhile, a risk of a signal crosstalk can be reduced where the capacitor is provided.

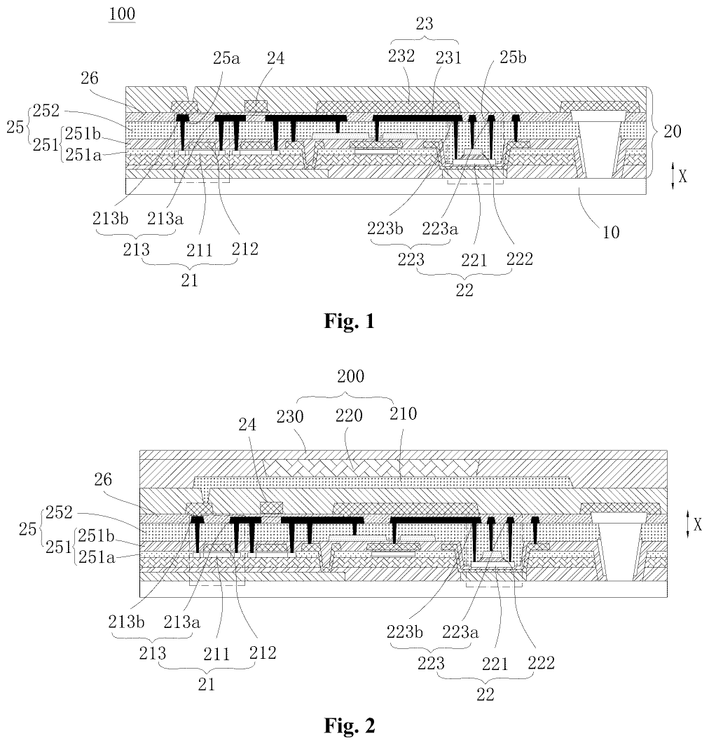

Referring to FIG. 1, the embodiments of the present application provide an array base plate 100 including a substrate 10 and a device layer 20, the device layer 20 is stacked on a side of the substrate 10 along a thickness direction X thereof, the device layer 20 includes a first type transistor 21, a second type transistor 22, and a capacitor 23, the first type transistor 21 includes a first source-drain electrode 213, the second type transistor 22 includes a second source-drain electrode 223, and the capacitor 23 includes a first electrode plate 231 and a second electrode plate 232. Here, the first electrode plate 231 is provided on the same layer as at least one of the first source-drain electrode 213 and the second source-drain electrode 223, and the second electrode plate 232 is provided on a side of the first type transistor 21 and the second type transistor 22 away from the substrate 10 along the thickness direction X.

Optionally, the substrate 10 may be a hard substrate or, of course, a flexible substrate.

Optionally, one of the first type transistor 21 and the second type transistor 22 may be a low temperature poly-silicon thin film transistor, and the other may be an oxide thin film transistor.

Optionally, the first type transistor 21 includes the first source-drain electrode 213, which may be understood that the first source-drain electrode 213 of the first type transistor 21 includes a first source 213a and a first drain 213b.

Optionally, the second type transistor 22 includes the second source-drain electrode 223, which may be understood that the second source-drain electrode 223 of the second type transistor 22 includes a second source 223a and a second drain 223b.

Optionally, the first source-drain electrode 213 and the second source-drain electrode 223 may be provided in separate layers, that is, provided in different layers, and under a condition that the first source-drain electrode 213 and the second source-drain electrode 223 are provided in separate layers, the first electrode plate 231 may be provided on the same layer as one of the first source-drain electrode 213 and the second source-drain electrode 223.

Optionally, the first source-drain electrode 213 and the second source-drain electrode 223 may be provided on the same layer, that is, the first electrode plate 231 may be provided on the same layer as the first source-drain electrode 213 and the second source-drain electrode 223.

In the array base plate 100 according to the embodiments of the present application, the device layer 20 of the array base plate 100 includes the first type transistor 21, the second type transistor 22, and the capacitor 23, the first type transistor 21 includes the first source-drain electrode 213, the second type transistor 22 includes the second source-drain electrode 223, and the first electrode plate 231 of the capacitor 23 is provided on the same layer as at least one of the first source-drain electrode 213 and the second source-drain electrode 223, the second electrode plate 232 of the capacitor 23 is provided on a side of the first type transistor 21 and the second type transistor 22 away from the substrate 10 along the thickness direction X, that is, the second electrode plate 232 is provided above the first type transistor 21 and the second type transistor 22, and the second electrode plate 232 of the capacitor 23 may be extended or offset outwards to increase the capacitance area, to satisfy a requirement of a high resolution, and reducing a crosstalk along a vertical direction.

In some embodiments, the first electrode plate 231 is provided on the same layer as the first source-drain electrode 213 and the second source-drain electrode 223.

In the array base plate 100 according to the embodiments of the present application, by providing the first electrode plate 231 on the same layer as the first source-drain electrode 213 and the second source-drain electrode 223, the first source-drain electrode 213 of the first type transistor 21 and the second source-drain electrode 223 of the second type transistor 22 may be manufactured on the same layer, only one mask is needed, and the manufacturing process can be reduced.

In one embodiment, in the array base plate 100 according to the embodiments of the present application, the first type transistor 21 includes a first active region 211, a first gate 212, and a first source-drain electrode 213, and the second type transistor 22 includes a second active region 221, a second gate 222, and a second source-drain electrode 223. The first active region 211 and the second active region 221 are provided on different layers, the first gate 212 and the second gate 222 are provided on different layers, and the first source-drain electrode 213 is provided on the same layer as the second source-drain electrode 223.

In some embodiments, a side of the first active region 211 and the second active region 221 away from the substrate 10 along the thickness direction X is covered by a first insulation layer group 25, the first insulation layer group 25 is provided with a first via 25a and a second via 25b, the first source-drain electrode 213 is connected to the first active region 211 through the first via 25a, and the second source-drain electrode 223 is connected to the second active region 221 through the second via 25b. Here, an orthographic projection of the second electrode plate 232 on the substrate is staggered with an orthographic projection of the first via 25a or the second via 25b on the substrate 10.

Optionally, the orthographic projection of the second electrode plate 232 on the substrate 10 may be staggered with the orthographic projection of the first via 25a on the substrate 10, or, of course, the orthographic projection of the second electrode plate 232 on the substrate 10 may be staggered with the orthographic projection of the second via 25b on the substrate 10. In some embodiments, the orthographic projection of the second electrode plate 232 on the substrate 10 may be staggered with the orthographic projections of the first via 25a and the second via 25b on the substrate 10.

With the above arrangement, an overlap area between the second electrode plate 232 and at least one of the first type transistor 21 and the second type transistor 22 is reduced along the thickness direction X, the vertical crosstalk reduced, and performance of the array base plate 100 is ensured.

In some embodiments, the first type transistor 21 may be the low temperature poly-silicon thin film transistor, and the second type transistor 22 may be the oxide thin film transistor.

In some embodiments, the first insulation layer group 25 includes a first sub-insulation layer 251 covering at least one of the first active region 211 and the second active region 221, the first sub-insulation layer includes a third insulation layer 251a and a fourth insulation layer 251b stacked along the thickness direction X, the third insulation layer 251a is located between the substrate and the fourth insulation layer 251b, and a thickness of the third insulation layer 251a ranges from 1200 Å to 2000 Å.

In one embodiment, the first sub-insulation layer 251 may cover the first active region 211. The first gate 212 and the first active region 211 are insulated from each other by the first sub-insulation layer 251.

In one embodiment, the first sub-insulation layer 251 may also cover the second active region 221, the second gate 222 and the second active region 221 are insulated from each other by the first sub-insulation layer 251.

In one embodiment, a material of a part of the first sub-insulation layer 251 covering the first active region 211 and a material of a part of the first sub-insulation layer 251 covering the second active region 221 may be the same and may be manufactured in different steps, and thus an insulation requirement is satisfied while manufacturing in different steps facilitates that the first active region and the second active region are manufactured in different steps. In one embodiment, the material of the first sub-insulation layer 251 may include silicon oxide or silicon nitride, and, of course, may include both silicon oxide and silicon nitride.

Optionally, the thickness of the third insulation layer 251a ranges from 1200 Å to 2000 Å, and includes two ands, 1200 Å to 2000 Å, and optionally, the thickness of the third insulation layer 251a ranges from 1400 Å to 1800 Å, optionally, 1500 Å, 1600 Å, 1700 Å, and the like.

In the array base plate 100 according to the embodiments of the present application, the first sub-insulation layer 251 covers at least one of the first active region 211 and the second active region 221, and the thickness of the third insulation layer 251a ranges from 1200 Å to 2000 Å, and a grain boundary repair of the first type transistor 21 can be considered while a device of the second type transistor 22 is not affected. Further, an increase of an electric field within an interface of the first sub-insulation layer 251 is conducive to inhibit an up-tail phenomenon of a cut-off region of the first type transistor 21, and a leakage current is reduced.

In one embodiment, the first sub-insulation layer 251 includes a silicon nitride layer and a silicon oxide layer stacked along the thickness direction X, the silicon oxide layer is located on a side of the silicon nitride layer close to the substrate 10, and a thickness of the silicon nitride layer is less than or equal to 1000 Å, optionally less than 600 Å.

With the above arrangement, a distance between an H barrier layer (such as the second insulation layer 251b) above the third insulation layer 251a and the first active region 211 of the first type transistor 21 can be reduced effectively, a grain boundary activation and repair of the first type transistor 21 is considered, and a thickness of the H barrier layer (also referred to as an H shield layer, which is used to block diffusion of H and does not generate H or has a very low H content) and a difficulty of a process debugging are reduced. Meanwhile, the presence of an electric field in the double-layer structure may be helpful for inhibiting the up-tail phenomenon of the cut-off region of the first type transistor 21 and reducing the leakage current.

In some embodiments, the first insulation layer group 25 further includes a second sub-insulation layer 252 provided on a side of the first sub-insulation layer 251 away from the substrate 10 along the thickness direction X, and a thickness of the second sub-insulation layer 252 ranges from 3000 Å to 8000 Å.

Optionally, the thickness of the second sub-insulation layer 252 is any value between 3000 Å and 8000 Å, including two ends, 3000 Å and 8000 Å. The thickness of the second sub-insulation layer 252 may further optionally range from 4000 Å to 7000 Å, optionally 5000 Å, 5500 Å, 6000 Å, and 6500 Å.

Optionally, the first gate 212 and the first source-drain electrode 213 may be insulated by the second sub-insulation layer 252.

Optionally, the second sub-insulation layer 252 may include silicon oxide.

See formula (1) and formula (2):

$$Δ {V}_{coup} = \frac{{C}_{p}}{{C}_{p} + Cst} Δ V \qquad ( 1 )$$

$${C}_{p} = \frac{{ε}_{ILD} \cdot S}{d} \qquad ( 2 )$$

Here:
Cₚ is a parasitic capacitor formed by overlapping signal lines; Cst is the main capacitor; ΔV is jump potential of a jump signal such as Vdata; ΔV_{coup} is coupling potential caused by the parasitic capacitor and the signal jump; ε_{ILD} is a dielectric constant of a dielectric layer of the second sub-insulation layer; S is an overlapping area between the signal lines composing the parasitic capacitor; d is a thickness of the dielectric layer of the second sub-insulation layer;

It may be known from the calculation formula of the coupling potential that the increase of the main capacitor and the decrease of the parasitic capacitor p are both beneficial for reducing a coupling effect. From the perspective of reducing the parasitic capacitor, according to the calculation formula (2) of the capacitance, the overlapping area between the signal lines is reduced and ε_{ILD} is reduced. Further, the thickness of the second sub-insulation layer 252 ranges from 3000 Å to 8000 Å, and the crosstalk caused by the coupling can be reduced, and the ability to implement a via etching process can be considered. Furthermore, by increasing the thickness of the second sub-insulation layer 252, the jump Data signal may be provided on the same layer as the second electrode plate 232, and may be laterally shielded by a power supply signal line, and the capacitor structure does not need an alignment design, and the capacitor structure may be laterally or vertically extended to increase the capacitance area. Therefore, an auxiliary capacitor structure does not need to be added, to satisfy the requirement of the high resolution and reducing the crosstalk.

In some embodiments, the array base plate 100 according to the embodiments of the present application further includes a second insulation layer 26 covering the first source-drain electrode 213 and the second source-drain electrode 223.

In one embodiment, a layer structure where the second electrode plate 232 is located is insulated from a layer structure where the first source-drain electrodes 213 and the second source-drain electrodes 223 are located by the second insulation layer 26.

In one embodiment, the second insulation layer 26 may include silicon nitride, and optionally, a thickness of the second insulation layer 26 may be from 1000 Å to 1300 Å, optionally 1100 Å, 1150 Å, 1200 Å, 1250 Å, and the like.

In the array base plate 100 according to the embodiments of the present application, a requirement that the layer structure where the second electrode plate 232 is located and the layer structure where the first source-drain electrode 213 and the second source-drain electrode 223 are located are insulated from each other can be satisfied by the second insulation layer 26, to improve the safety and the performance. In addition, the thickness of the second insulation layer 26 is within the above range, and a distance between the first electrode plate 231 and the second electrode plate 232 can be moderate to satisfy a requirement for a capacitance magnitude on the basis of satisfying the insulation requirement.

In some embodiments, in the array base plate 100 according to the embodiments of the present application, the device layer 20 further includes a power supply line 24 provided on the same layer as the second electrode plate 232.

Optionally, a patterned metal layer is formed on a side of the second insulation layer 26 away from the substrate 10, and includes a first power supply line 24, the first power supply line 24 is located on the same metal layer as the second electrode plate 232, and the second electrode plate 232 may be directly or indirectly connected to the first power supply line 24 to obtain fixed potential.

It may be understood that the first power supply line 24 and the second electrode plate 232 are provided in different regions and directly or indirectly electrically connected, which is not limited in the present application. In some embodiments, at least a part of the first power supply line 24 may be reused as the second electrode plate 232, which can also satisfy a functional requirement of the capacitor 23.

In some embodiments, in the array base plate 100 according to the embodiments of the present application, the first electrode plate 231 is electrically connected to at least one of the first gate 212 and the second gate 222, and the second electrode plate 232 is electrically connected to at least one of the first source-drain electrode 213 and the second source-drain electrode 223.

With the above arrangement, a functional requirement of a pixel driving circuit formed by the capacitor 23 along with the first type transistor 21 and the second type transistor 22 can be satisfied, and a driving requirement for the light-emitting element can be satisfied.

In some embodiments, the device layer 20 further includes a scanning signal line and a data signal line, an orthographic projection of the second electrode plate 232 on the substrate 10 covers an orthographic projection of at least a part of at least one of the first electrode plate 231, the scanning signal line and the data signal line on the substrate 10.

Optionally, the scanning signal line may be provided on the same layer as one of the first gate 212 and the second gate 222.

Optionally, the data signal line may be provided on the same layer as at least one of the first source-drain electrode 213 and the second source-drain electrode 223.

Optionally, the orthographic projection of the second electrode plate 232 on the substrate 10 may cover the orthographic projection of one of the first electrode plate 231, the scanning signal line and the data signal line on the substrate 10, or may cover orthographic projections of more than two of the first electrode plate 231, the scanning signal line and the data signal line on the substrate 10, and, of course, may cover orthographic projections of all three on the substrate 10.

In the array base plate 100 according to the embodiments of the present application, the orthographic projection of the second electrode plate 232 on the substrate 10 covers the orthographic projection of at least a part of at least one of the first electrode plate 231, the scanning signal line, and the data signal line on the substrate 10, and a capacitance requirement can be satisfied, and the second electrode plate 232 can also have a shielding effect to block an electromagnetic signal from an upper part, a side part, and a lower part of a screen body, to prevent the electromagnetic signal from the upper part, the side part, and the lower part of the screen body from interfering with a signal within the screen body.

As shown in FIG. 2, the embodiments of the present application provide a display panel including the above array base plate 100, and in one embodiment, the display panel may further include an OLED device 200 that may include an anode 210, a light-emitting material layer 220, and a cathode 230, and the OLED device 200 may be a top light-emitting device. The anode 210 is connected to the first source-drain electrode 213 of the first type transistor 21.

The display panel may be a flexible display panel or a rigid display panel, and the display panel is applicable to a wearable device, such as a smart bracelet, a smart watch, a Virtual Reality (VR), and the like, and applicable to an e-book, an electronic newspaper, a television, a portable computer, and a foldable and rollable OLED flexible display and illumination, and the like.

The display panel according to the embodiments of the present application includes the array base plate 100 according to the above various embodiments, and the second electrode plate 232 of the capacitor 23 is provided on the side of the first type transistor 21 and the second type transistor 22 away from the substrate 10 along the thickness direction X, that is, the second electrode plate 232 is provided above the first type transistor 21 and the second type transistor 22, and the second electrode plate 232 of the capacitor 23 may be extended or offset outwards to increase the capacitance area, and the resolution of the display panel can be increased.

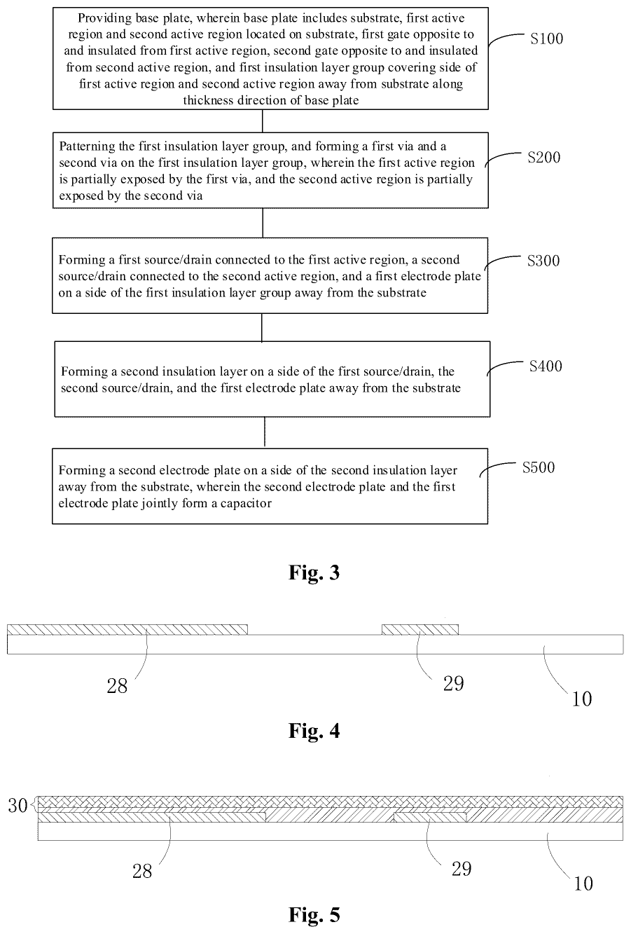

As shown in FIG. 3 to FIG. 17, the embodiments of the present application further provide a method for manufacturing an array base plate 100, which can be used for manufacturing the array base plate 100 according to the above various embodiments, and the method includes S100 to S500.

S100, as shown in FIG. 4 to FIG. 14, providing a base plate, here, the base plate includes a substrate 10, a first active region 211, a first gate 212 opposite to and insulated from the first active region 211, a second active region 221, a second gate 222 opposite to and insulated from the second active region 221, and a first insulation layer group 25 covering a side of the first active region 211 and the second active region 221 away from the substrate 10 along a thickness direction X;

S200, as shown in FIG. 14, patterning the first insulation layer group 25, and forming a first via 25a and a second via 25b on the first insulation layer group 25, here, the first active region 211 is partially exposed by the first via 25a, and the second active region 221 is partially exposed by the second via 25b;

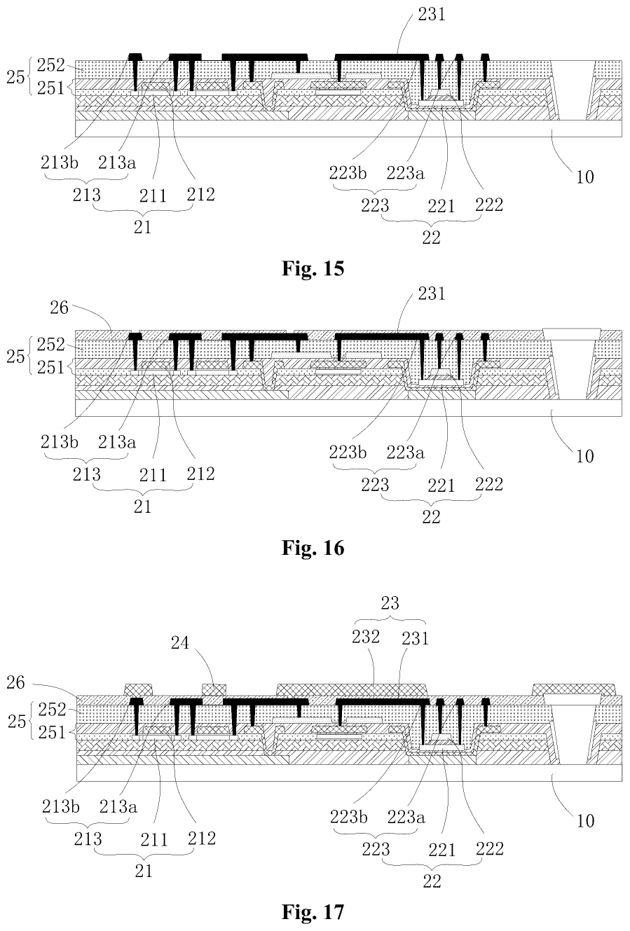

S300, as shown in FIG. 15, forming a first source-drain electrode 213 connected to the first active region 211, a second source-drain electrode 223 connected to the second active region 221, and a first electrode plate 231 on a side of the first insulation layer group 25 away from the substrate 10;

S400, as shown in FIG. 16, forming a second insulation layer 26 on a side of the first source-drain electrode 213, the second source-drain electrode 223, and the first electrode plate 231 away from the substrate 10; and

S500, as shown in FIG. 17, forming a second electrode plate 232 on a side of the second insulation layer 26 away from the substrate 10, here, the second electrode plate 232 and the first electrode plate 231 jointly form a capacitor 23.

In one embodiment, the base plate provided in step S100 may be manufactured in advance, or, of course, may be manufactured in situ.

In some embodiments, step S100 includes:

as shown in FIG. 4, forming a patterned first metal layer on the substrate 10, here, the first metal layer includes a second power supply line 28 located at the bottom and a back shield metal 29, and the first metal layer may include molybdenum metal;

as shown in FIG. 5, forming a buffer layer 30 on the patterned first metal layer, here, the buffer layer 30 may include a silicon oxide layer and a silicon nitride layer;

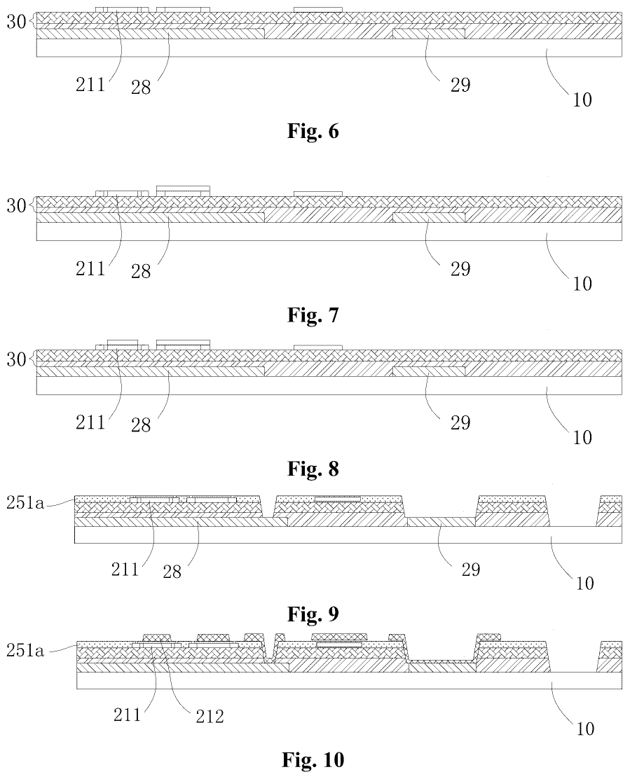

as shown in FIG. 6 to FIG. 8, forming a patterned first active layer on the buffer layer 30 and performing light doping and heavy doping to form the first active region 211;

as shown in FIG. 9, forming a third insulation layer 251a on a side of the first active region 211 away from the substrate 10 and patterning the third insulation layer 251a, and the back shield metal 29 is exposed by the third insulation layer 251a, here, the third insulation layer 251a may include at least one of silicon oxide and silicon nitride;

as shown in FIG. 10, forming the first gate 212 and a first metal line on the third insulation layer 251a, here, the first gate 212 is opposite to the first active region 211, and the first metal line is electrically connected to the second power supply line 28;

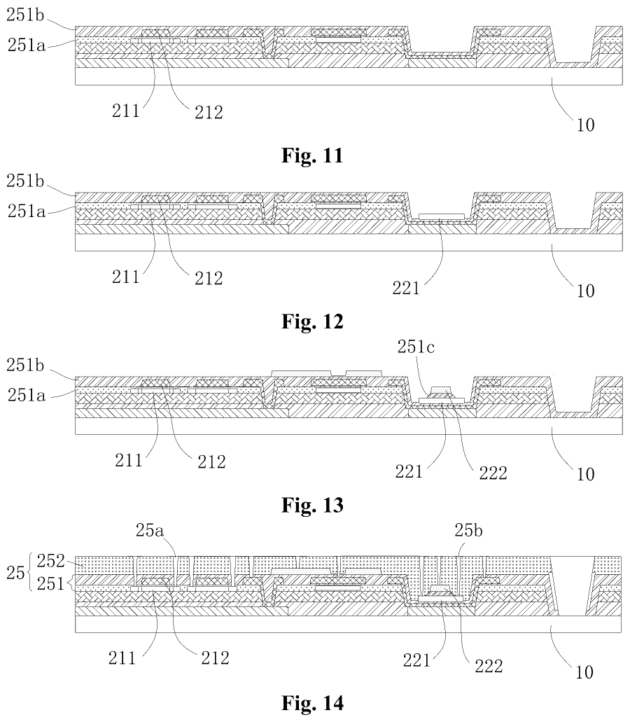

as shown in FIG. 11, forming a fourth insulation layer 251b on a side of the first gate 212 and the first metal line away from the substrate 10, here, the fourth insulation layer 251b includes at least one of silicon oxide and silicon nitride;

as shown in FIG. 12, forming a patterned second active layer in a predetermined region on a side of the fourth insulation layer 251b away from the substrate 10 to form the second active region 221;

as shown in FIG. 13, forming a fifth insulation layer 251c and the second gate 222 on a side of the second active region 221 away from the substrate 10, here, the third insulation layer 251a, the fourth insulation layer 251b, and the fifth insulation layer 251c may be understood as the above first sub-insulation layer 251; and

as shown in FIG. 14, forming a second sub-insulation layer 252 on a side of the second gate 222 and the fourth insulation layer 251b away from the substrate 10, here, the second sub-insulation layer 252 and the first sub-insulation layer 251 form the first insulation layer group 25, and the base plate is manufactured.

Optionally, with further reference to FIG. 14, in step S200, the first insulation layer group 25 is patterned, the first via 25a and the second via 25b are formed on the first insulation layer group 25, the first via 25a starts extending from a side of the first insulation layer group 25 away from the substrate 10 to the first active region 211, and the first active region 211 is partially exposed by the first via 25a, and the second via 25b starts extending from the side of the first insulation layer group 25 away from the substrate 10 to the second active region 221, and the second active region 221 is partially exposed by the second via 25b.

Optionally, as shown in FIG. 15, in step S300, the metal layer may be formed on the side of the first insulation layer group 25 away from the substrate 10 and patterned, and the metal layer may include titanium aluminum titanium to form the first source-drain electrode 213 connected to the first active region 211, the second source-drain electrode 223 connected to the second active region 221, and the first electrode plate 231.

Optionally, as shown in FIG. 16, in step S400, the manufactured second insulation layer 26 may include silicon oxide and/or silicon nitride.

Optionally, as shown in FIG. 17, in step S500, when the second electrode plate 232 is manufactured, and a first power supply line 24 at the top and the like provided on the same layer as the second electrode plate 232 may be formed synchronously.

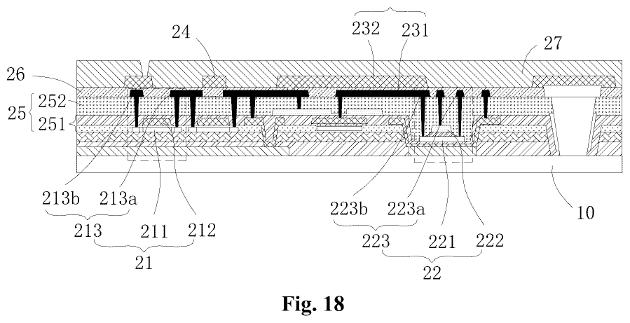

Optionally, as shown in FIG. 18, after step S500, the method further includes: manufacturing a planarization layer 27 on a side of a layer structure away from the substrate 10, here, the second electrode plate 232 is located in the layer structure.

The method for manufacturing the array base plate 100 according to the embodiments of the present application may be used for manufacturing the array base plate 100 according to the above various embodiments. In the manufacturing method, the first electrode plate 231 of the capacitor 23 is provided on the same layer as at least one of the first source-drain electrode 213 and the second source-drain electrode 223, and the second electrode plate 232 of the capacitor 23 is provided on a side of the first source-drain electrode 213 and the second source-drain electrode 223 away from the substrate 10 along the thickness direction X, that is, the second electrode plate 232 is provided above the first type transistor 21 and the second type transistor 22, and the second electrode plate 232 of the capacitor 23 may be extended or offset outward to increase the capacitance area, to satisfy the requirement of a high resolution.

Although the present application has been described with reference to the embodiments, various modifications can be made thereto and components thereof can be replaced with their equivalents without departing from the scope of the present application. In particular, various features described in various embodiments can be combined in any manner as long as there is no structural conflict. The present application is not limited to the specific embodiments described herein, and includes all solutions that fall within the scope of the claims.

What is claimed is:

1. An array base plate, comprising:
a substrate;
a device layer stacked on a side of the substrate along a thickness direction thereof, wherein the device layer comprises a first type transistor, a second type transistor, and a capacitor, the first type transistor comprises a first source-drain electrode, the second type transistor comprises a second source-drain electrode, and the capacitor comprises a first electrode plate and a second electrode plate;
wherein the first electrode plate is provided on a same layer as at least one of the first source-drain electrode and the second source-drain electrode, and the second electrode plate is provided on a side of the first type transistor and the second type transistor away from the substrate along the thickness direction.

2. The array base plate according to claim 1, wherein the first electrode plate is provided on a same layer as the first source-drain electrode and the second source-drain electrode.

3. The array base plate according to claim 1, wherein the device layer further comprises a power supply line provided on a same layer as the second electrode plate.

4. The array base plate according to claim 1, wherein the device layer further comprises a power supply line, and at least a part of the power supply line is reused as the second electrode plate.

5. The array base plate according to claim 1, wherein the first type transistor further comprises a first active region, the second type transistor further comprises a second active region, a side of the first active region and the second active region away from the substrate along the thickness direction is covered by a first insulation layer group, the first insulation layer group is provided with a first via and a second via, the first source-drain electrode is connected to the first active region through the first via, and the second source-drain electrode is connected to the second active region through the second via;
wherein an orthographic projection of the second electrode plate on the substrate is staggered with an orthographic projection of the first via or the second via on the substrate.

6. The array base plate according to claim 5, wherein the first insulation layer group comprises a first sub-insulation layer covering at least one of the first active region and the second active region, the first sub-insulation layer comprises a third insulation layer and a fourth insulation layer stacked along the thickness direction, the third insulation layer is located between the substrate and the fourth insulation layer, and a thickness of the third insulation layer ranges from 1200 Å to 2000 Å.

7. The array base plate according to claim 6, wherein the thickness of the third insulation layer ranges from 1400 Å to 1800 Å.

8. The array base plate according to claim 6, wherein the third insulation layer comprises a silicon nitride layer and a silicon oxide layer stacked along the thickness direction, and a thickness of the silicon nitride layer is less than or equal to 1000 Å.

9. The array base plate according to claim 6, wherein the first insulation layer group further comprises a second sub-insulation layer provided on a side of the first sub-insulation layer away from the substrate along the thickness direction, and a thickness of the second sub-insulation layer ranges from 3000 Å to 8000 Å.

10. The array base plate according to claim 9, wherein the second sub-insulation layer comprises silicon oxide.

11. The array base plate according to claim 1, wherein the first type transistor further comprises a first gate, the second type transistor further comprises a second gate, the first electrode plate is electrically connected to at least one of the first gate and the second gate, and the second electrode plate is electrically connected to at least one of the first source-drain electrode and the second source-drain electrode.

12. The array base plate according to claim 11, wherein the first gate and the second gate are provided on different layers.

13. The array base plate according to claim 1, the array base plate further comprises a second insulation layer covering the first source-drain electrode and the second source-drain electrode.

14. The array base plate according to claim 13, wherein a thickness of the second insulation layer ranges from 1000 Å to 1300 Å.

15. The array base plate according to claim 1, wherein one of the first type transistor and the second type transistor is a low temperature poly-silicon thin film transistor, and the other is an oxide thin film transistor.

16. The array base plate according to claim 1, wherein the device layer further comprises a scanning signal line and a data signal line, an orthographic projection of the second electrode plate on the substrate covers an orthographic projection of at least a part of at least one of the first electrode plate, the scanning signal line and the data signal line on the substrate.

17. A display panel, comprising the array base plate according to claim 1.

18. A method for manufacturing an array base plate, comprising:
providing a base plate, wherein the base plate comprises a substrate, a first active region and a second active region located on the substrate, a first gate opposite to and insulated from the first active region, a second gate opposite to and insulated from the second active region, and a first insulation layer group covering a side of the first active region and the second active region away from the substrate along a thickness direction of the base plate;
patterning the first insulation layer group, and forming a first via and a second via on the first insulation layer group, wherein the first active region is partially exposed by the first via, and the second active region is partially exposed by the second via;
forming a first source-drain electrode connected to the first active region, a second source-drain electrode connected to the second active region, and a first electrode plate on a side of the first insulation layer group away from the substrate;
forming a second insulation layer on a side of the first source-drain electrode, the second source-drain electrode, and the first electrode plate away from the substrate; and
forming a second electrode plate on a side of the second insulation layer away from the substrate, wherein the second electrode plate and the first electrode plate jointly form a capacitor.
